(19) United States
(12) Patent Application Publication
(10) Pub. No.: US 2015/0228828 A1
(43) Pub. Date: Aug. 13, 2015

(54) SOLAR CELL MODULE AND METHOD OF FABRICATING THE SAME

(71) Applicant: LG INNOTEK CO., LTD., Seoul (KR)

(72) Inventor: Se Han Kwon, Seoul (KR)

(21) Appl. No.: 14/361,619

(22) PCT Filed: Nov. 27, 2012
(86) PCT No.: PCT/KR2012/010123

§ 371 Date: May 29, 2014

(30) Foreign Application Priority Data
Nov. 29, 2011 (KR) 10-2011-0126251

(51) Int. Cl. H01L 31/049; H02S 30/10

(52) U.S. Cl. CPC H01L 31/049; H02S 30/10

(57) ABSTRACT

Disclosed are a solar cell module and a method of fabricating the same. The solar cell module includes a solar cell panel; a protective substrate on the solar cell panel; a buffer portion between the solar cell panel and the protective substrate; a frame surrounding the solar cell panel and receiving the solar cell panel therein; and a sealing portion between the solar cell panel and the frame, wherein the sealing portion extends from the buffer portion. The method of fabricating a solar cell module includes the steps: preparing a solar cell panel; preparing a protective substrate on the solar cell panel; preparing a filler between the solar cell panel and the protective substrate; placing a frame that receives the solar cell panel and the protective substrate therein; and laminating the filler, wherein the laminating of the filler is performed after the placing of the frame.

### TECHNICAL FIELD

The embodiment relates to a solar cell module and a method of fabricating the same.

### BACKGROUND ART

A solar cell module to convert light energy into electrical energy through photo-electric conversion effect has been extensively used as a device to obtain non-pollution energy contributing to the conservation of global environment.

As the photoelectric conversion effect is improved, a great number of solar cell systems having a solar cell module are installed even for home use.

In order to output power generated from the solar cell module including solar cells that generate power from the light of the sun to the outside, conductors acting as positive and negative electrodes are provided in the solar cell module, and terminals of the conductors, which serve as connectors connected to a cable of outputting current to the outside, are withdrawn out of a photovoltaic module.

According to the solar cell module, a buffer sheet for protecting the solar cell panel from an external physical shock is formed, and a lamination process is performed for forming the buffer sheet. Then, a frame for receiving the solar cell panel is mounted. However, due to the above processes, the entire process is complex and the process time is lengthened. In addition, since the frame is mounted later, a gap is formed between the solar cell panel and the frame, so the solar cell module represents weakness against external environment.

### DISCLOSURE OF INVENTION

### Technical Problem

The embodiment provides a solar cell module having improved reliability.

### Solution to Problem

According to the embodiment, there is provided a solar cell module including a solar cell panel; a protective substrate on the solar cell panel; a buffer portion between the solar cell panel and the protective substrate; a frame surrounding the solar cell panel and receiving the solar cell panel therein; and a sealing portion between the solar cell panel and the frame, wherein the sealing portion extends from the buffer portion.

According to the embodiment, there is provided a method of fabricating a solar cell module. The method includes the steps of: preparing a solar cell panel; preparing a protective substrate on the solar cell panel; preparing a filler between the solar cell panel and the protective substrate; placing a frame that receives the solar cell panel and the protective substrate therein; and laminating the filler, wherein the laminating of the filler is performed after the placing of the frame.

### Advantageous Effects of Invention

As described above, the solar cell module according to the embodiment includes the buffer sheet including the buffer portion and the sealing portion. A gap between the solar cell panel and the frame may be removed through the sealing portion, so that the solar cell panel can be effectively protected from external environment. In addition, since the sealing portion has s strong adhesive strength so that the durability can be improved. Thus, the reliability of the solar cell module can be improved.

The method of fabricating a solar cell module according to the embodiment includes the performing of the lamination and the placing of the frame. The performing of the lamination is carried out after the placing of the frame. That is, the filler may be laminated at the same time as the frame is mounted. Thus, the entire process may be simplified.

Further, the sealing portion and the buffer portion may be formed through the same process, so that the entire process may be simplified.

### BRIEF DESCRIPTION OF DRAWINGS

FIG. 1 is an exploded perspective view showing a solar cell module according to the embodiment;

FIG. 2 is a sectional view taken along line A-A′ in FIG. 1;

FIG. 3 is a perspective view showing a solar cell panel included in the solar cell module according to the embodiment; and

FIG. 4 is a sectional view illustrating a method of fabricating the solar cell module according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each layer (or film), each region, each pattern, or each structure shown in the drawings may be exaggerated, omitted or schematically drawn for the purpose of convenience or clarity. In addition, the size of the layer (or film), the region, the pattern, or the structure does not utterly reflect an actual size.

Hereinafter, the embodiment will be described with reference to accompanying drawings in detail.

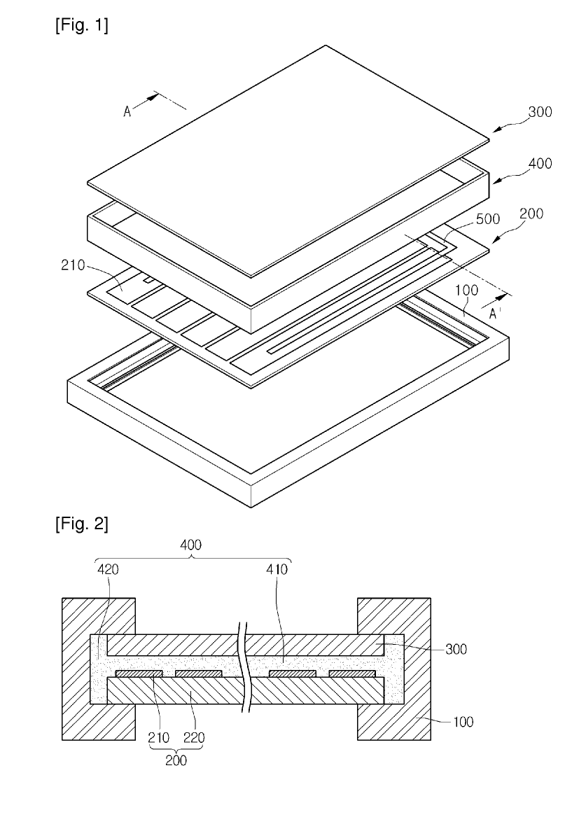

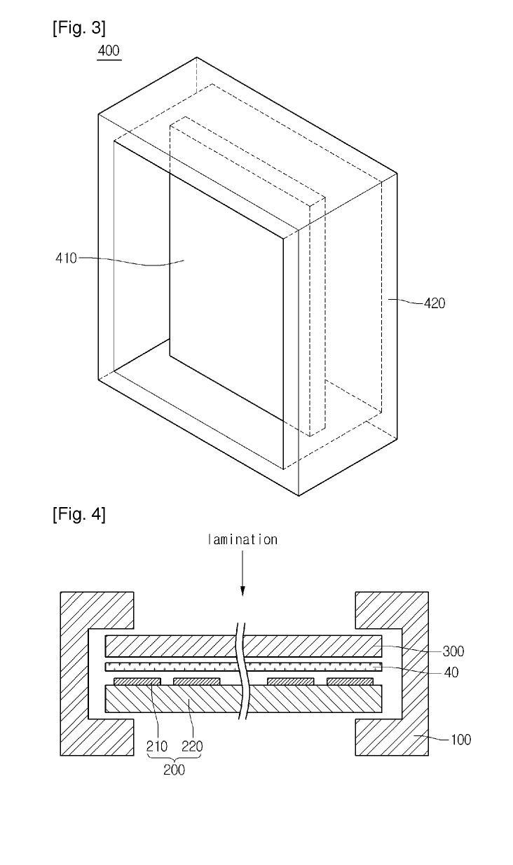

First, the solar cell module according to the first embodiment will be described in detail with reference to FIGS. 1 to 3. FIG. 1 is an exploded perspective view showing a solar cell module according to the embodiment. FIG. 2 is a sectional view taken along line A-A′ in FIG. 1. FIG. 3 is a perspective view showing a solar cell panel included in the solar cell module according to the embodiment.

Referring to FIGS. 1 to 3, the solar cell module according to the embodiment includes a frame 100, a solar cell panel 200, a protective substrate 300, and a buffer sheet 400.

The frame 100 is disposed on a side surface of the solar cell panel 200. The frame 100 accommodates the solar cell panel 200, the protective substrate 300 and the buffer sheet 400 therein. In detail, the frame 100 surrounds the side surface of the solar cell panel 200.

For example, the frame 100 may be a metal frame 100. In addition, the frame 100 may include aluminum, stainless steel or steel.

The solar cell panel 200 is disposed inside the frame 100. The solar cell panel 200 has a plate shape and includes a plurality of solar cells.

For example, the solar cells 210 may include a CIGS-based solar cell, a silicon-based solar cell, a dye-sensitized solar cell, a group II-VI compound semiconductor solar cell, or a group III-V compound semiconductor solar cell.

In addition, the solar cells 210 may be disposed on a transparent substrate such as a glass substrate.

The solar cells 210 may be arranged in the shape of a stripe. In addition, the solar cells 210 may be arranged in various shapes such as a matrix shape.

The bus bar 500 is disposed on the solar cell panel 200. The bus bar 500 makes contact with the top surfaces of two of the solar cells 210, and is electrically connected to the solar cells 210.

For example, the bus bar 500 includes a first bus bar and a second bus bar.

The first bus bar makes contact with a top surface of one outmost solar cell of the solar cells 210. The second bus bar makes direct contact with the top surface of the other outmost solar cell 210 of the solar cells 210.

The bus bar 500 may include a conductor, and for example, the material constituting the bus bar 500 may include copper (Cu).

The protective substrate 300 is disposed over the solar cell panel 200. The protective substrate 300 is provided in opposition to the solar cell panel 200.

The protective substrate 300 may be transparent and have a high strength. The material constituting the protective substrate 300 may include tempered glass.

The buffer sheet 400 includes a buffer portion 410 and a sealing portion 420.

The buffer portion 410 is interposed between the protective substrate 300 and the solar cell panel 200. The buffer portion 410 protects the solar cell panel 200 from the external physical shock. In addition, the buffer portion 410 prevents the protective substrate 300 from colliding with the solar cell panel 200.

The buffer portion 410 may perform an anti-reflective function so that a greater amount of light is incident onto the solar cell panel 200.

The sealing portion 420 is placed between the solar cell panel 200 and the frame 100. That is, the sealing portion 420 surrounds the solar cell panel 200 and the protective substrate 300 in the frame 100. The sealing portion 420 surrounds the rims of the solar cell panel 200 and the protective substrate 300.

A gap between the solar cell panel 200 and the frame 100 may be removed by sealing portion 420, so that the solar cell panel 200 may be effectively protected from an external environment. In addition, since the sealing portion 420 has a strong adhesive strength, the durability may be improved. Thus, the reliability of the solar cell module may be improved.

The sealing portion 420 extends from the buffer portion 410. The buffer and sealing portions 410 and 420 are integrally formed.

That is, the buffer and sealing portions 410 and 420 include the same material. The material constituting the buffer and sealing portions 410 and 420 may include ethylene vinyl acetate (EVA) resin.

The protective substrate 300 and the buffer sheet 400 are disposed inside the frame 100. In detail, the sides of the solar cell panel 200, the protective substrate 300 and the sealing portion 420 are fixedly inserted into the frame 100.

Hereinafter, a method of fabricating a solar cell module according to the embodiment will be described with reference to FIG. 4. In the following description, the details of structures and components the same as those of the first embodiment or extremely similar to those of the first embodiment will be omitted except for only structures and components making the difference from those of the first embodiment for the purpose of clear and simple explanation.

FIG. 4 is a sectional view illustrating the method of fabricating a solar cell module according to the embodiment.

Referring to FIG. 4, the method of fabricating a solar cell module includes preparing a solar cell panel, preparing a protective substrate, preparing a filler, placing a frame, and performing a lamination.

In the preparing of the solar cell panel 200, the solar cell panel 200 may be prepared.

In the preparing of the protective substrate 300, the protective substrate 300 may be placed on the solar cell panel 200.

In the preparing of the filler 40, the filler 40 may be prepared between the solar cell panel 200 and the protective substrate 300. The filler 40 may include resin.

In the placing of the frame 100, the frame 100 for receiving the solar cell panel 200 and the protective substrate 300 may be placed.

In the performing of the lamination, the filler 40 may be laminated. The lamination is performed after performing the placing of the frame 100. That is, the filler 40 may be laminated at the same time as the frame 100 is mounted. Thus, the process may be simplified.

In the performing of the lamination, a part of the filler 40 may surround the solar cell panel 200. In detail, in the performing of the lamination, the part of the filler 40 may be placed between the solar cell panel 200 and the frame 100. That is, in the performing of the lamination, a part of the filler 40 flows out to surround the solar cell panel 200 and the protective substrate 300 in the frame 100.

In the performing of the lamination, the filler 40 may be cured to form the buffer sheet (see, reference numeral 410 of FIG. 3). Thus, the buffer sheet 400 may include a buffer portion (see, reference numeral 410 in FIG. 3) placed between the solar cell panel 200 and the protective substrate 300, and a sealing portion (see, reference numeral 420 in FIG. 1) placed between the solar cell panel 200 and the frame 100.

According to the embodiment, the sealing portion 420 and the buffer portion 410 may be formed through the same process, so that the entire process may be simplified.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a solar cell panel;
a protective substrate on the solar cell panel;
a buffer portion between the solar cell panel and the protective substrate;
a frame surrounding the solar cell panel and receiving the solar cell panel therein; and
a sealing portion between the solar cell panel and the frame,
wherein the sealing portion extends from the buffer portion.

2. The solar cell module of claim 1, wherein the buffer portion and the sealing portion include a same material.

3. The solar cell module of claim 1, wherein the buffer portion and the sealing portion are integrally formed with each other.

4. The solar cell module of claim 1, wherein the sealing portion surrounds the solar cell panel and the protective substrate in the frame.

5. The solar cell module of claim 1, wherein the sealing portion surrounds rims of the solar cell panel and the protective substrate.

6-13. (canceled)

14. The solar cell module of claim 1, wherein the sealing portion extends form the buffer portion.

15. The solar cell module of claim 1, wherein the buffer and sealing portions are formed ethylene vinyl acetate (EVA) resin.

16. The solar cell module of claim 1, wherein the sides of the solar cell panel, the protective substrate, and the sealing portion are fixedly inserted into the frame.
